(19) United States
(12) Patent Application Publication
(10) Pub. No.: US 2009/0294060 A1
(43) Pub. Date: Dec. 3, 2009

(54) Semiconductor Device Manufacturing Apparatus Capable Of Reducing Particle Contamination

(76) Inventors: Hiroyuki Kobayashi, Kodaira (JP); Kenji Maeda, Sagamihara (JP); Kenetsu Yokogawa, Tsurugashima (JP); Masaru Izawa, Hino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/539,140

(22) Filed: Aug. 11, 2009

Related U.S. Application Data
(63) Continuation of application No. 11/668,038, filed on Jan. 29, 2007.

(30) Foreign Application Priority Data
Jul. 21, 2006 (JP) 2006-198877

(51) Int. Cl. H01L 21/465

(52) U.S. Cl. 156/345.1; 118/723 R; 257/E21.485

(57) ABSTRACT

A semiconductor device manufacturing apparatus includes a process chamber, a conveyance chamber, a conveyance robot, a lock chamber, and a heating unit or temperature adjusting unit for reducing adherence of particles onto a substance to be processed by a thermo-phoretic force. The heating unit enables control of a temperature of the substance to be processed to be higher than a temperature of an inner wall or structural body of the process chamber or the conveyance chamber or the conveyance robot or the lock chamber, in conveying the substance to be processed. The temperature adjusting unit enables adjustment of a temperature of an inner wall or structural body of the process chamber or the conveyance chamber or the lock chamber to be lower than a temperature of the substance to be processed, in conveying the substance to be processed.

### CROSS REFERENCE TO RELATED APPLICATION

This application is a continuation of U.S. application Ser. No. 11/668,038, filed Jan. 29, 2007, the contents of which are incorporated herein by reference.

### BACKGROUND OF THE INVENTION

The present invention relates to a semiconductor device manufacturing apparatus capable of reducing particle contamination.

In a manufacturing process of a semiconductor device such as DRAM or a micro processor, plasma etching or plasma CVD is widely used. As one problem in processing of a semiconductor device using plasma, reduction of numbers of particles adhering onto a substance to be processed is included. For example, adherence of the particles onto a fine pattern of the substance to be processed during etching processing inhibits local etching at that part, which could generate defect such as disconnection, resulting in yield reduction.

As a control method for transporting the particles to prevent adherence of the particles onto the substance to be processed in a plasma processing apparatus, for example, a method for using gas flow, or a method for controlling transportation of charged particles by Coulomb force (see JP-A-5-47712 corresponding to U.S. Pat. No. 5,401,356), or a method for controlling transportation of particles by a magnetic field (see JP-A-11-162946) has been devised.

### SUMMARY OF THE INVENTION

First of all, explanation on behavior of the particles in plasma is given below. The particles float at the vicinity of the boundary of a sheath and plasma. This reason is explained using FIG. 5, on the particles floating just above the substance to be processed, as an example. Note that, in FIG. 5, it was assumed for simplicity that there is no gas flow or gas temperature gradient in a vertical direction relative to the substance 2 to be processed. The particles 60 are known to be negatively charged in plasma. In addition, the substance 2 to be processed is also negatively charged relative to plasma. Therefore, the particles 60 receive repulsion force by Coulomb force from the substance 2 to be processed. On the other hand, ions flow into the substance 2 to be processed, and the particles 60 receive force (ion drag) in a direction to be pushed toward the substance 2 to be processed when the ions collide to the particles 60.

Further, by gravitational force, the particles 60 receive force in a direction of falling down onto the substance 2 to be processed. Therefore, the particles 60 float at the vicinity of the height where total of ion drag and gravitational force balances with Coulomb force. This float height almost coincides with a boundary between plasma and the sheath. In addition, in the case where gas flow is present, for example, in a direction parallel to the substance 2 to be processed, the particles 60 are transported in the gas flow direction along the boundary between plasma and the sheath, by gas viscous force

However, when plasma is cut off, balance between ion drag or Coulomb force is collapsed, causing a part of the floating particles falls onto the substance 2 to be processed. Therefore, it is necessary for the particles 60 not to fall onto the substance 2 to be processed, even when plasma is cut off.

When plasma is cut off, major forces acting on the particles are gravitational force, drag force of gas and thermo-phoretic force. Therefore, it is desirable that the particles are made not to adhere onto a wafer, utilizing theses forces in a process chamber or a transportation chamber, during transportation or before and after plasma processing.

In view of the above situation, it is an object of the present invention to provide a method for the particles not to fall down onto a wafer, by utilization of thermo-phoretic force. “Thermo-phoretic force” here means force exerting to particles when gas temperature gradient is present. For example, in the case shown by FIG. 5, gas temperature at the right side is designed to be higher than gas temperature at the left side, relative to the particles 60. In this case, force of gas molecules colliding to the right side of the particles 60 becomes larger than force of gas molecules colliding to the left side of the particles 60. In such a way, the particles 60 are transported to the left side, namely, in a direction where temperature is lower, by receiving the force.

The present invention is characterized in that, in a semiconductor device manufacturing apparatus which is equipped with: a process chamber; a unit for supplying gas to the process chamber; an exhausting unit to reduce pressure in the process chamber; a high frequency power source for plasma generation; a coil for generating a magnetic field; and a mounted electrode for mounting a substance to be processed, particles are transported in the circumference direction of the substance to be processed by thermo-phoretic force, by changing the magnetic field distribution, so as to make a plasma distribution at the surface of the substance to be processed, in a convex form, at ignition of the plasma or after completion of a predetermined processing, compared with the plasma distribution during the predetermined processing to the substance to be processed, and thus to generate temperature gradient of processing gas just above the substance to be processed.

In addition, the present invention is characterized in that, in a semiconductor device manufacturing apparatus which is equipped with: a process chamber; a conveyance chamber; a conveyance robot; and a lock chamber, the apparatus further has a heating unit for reducing adherence of particles onto a substance to be processed by thermo-phoretic force, by making temperature of the substance to be processed higher than that of the inner wall or structural body of the process chamber or the conveyance chamber or the conveyance robot or the lock chamber, in conveying the substance to be processed.

In the present invention, gas temperature gradient is created in a positive way, so as to reduce adherence of the particles onto the substance to be processed, by removing the particles from the substance to be processed by thermo-phoretic force, by which yield of a semiconductor device can be improved.

Other objects, features and advantages of the invention will become apparent from the following description of the embodiments of the invention taken in conjunction with the accompanying drawings.

### BRIEF DESCRIPTION OF THE DRAWINGS

FIG. 1 is an outline diagram of a first embodiment where the present invention is applied to a parallel flat plate type ECR plasma processing apparatus.

FIG. 2 is a diagram explaining process sequence.

FIGS. 3A and 3B are diagrams explaining plasma distribution and gas temperature distribution.

FIG. 4 is a diagram of experimental result explaining the effect of reducing particles.

FIG. 5 is a diagram explaining force exerting on the particles.

FIG. 6 is a diagram explaining a second embodiment to which the present invention is applied.

FIG. 7 is a diagram explaining a third embodiment to which the present invention is applied.

FIG. 8 is a diagram explaining a fourth embodiment to which the present invention is applied.

FIG. 9 is a diagram explaining process sequence.

FIG. 10 is a diagram explaining a fifth embodiment to which the present invention is applied.

FIGS. 11A and 11B are diagrams explaining a conveyance robot.

FIGS. 12A to 12C are diagrams explaining a heater installed at a conveyance arm.

FIG. 13 is a diagram explaining cross-section of a lock chamber.

FIGS. 14A and 14B are diagrams explaining a stage.

### DETAILED DESCRIPTION OF THE EMBODIMENTS

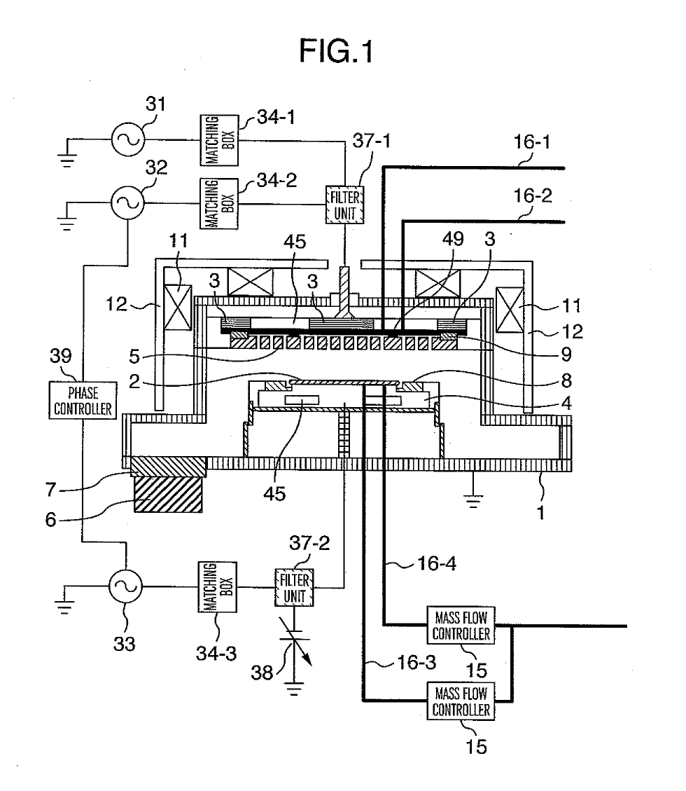

A first embodiment of the present invention is explained below by referring to FIG. 1 to FIG. 4. FIG. 1 shows an example of a parallel flat plate type UHF-ECR plasma processing apparatus. The process chamber 1 is grounded. At the upper part of the process chamber 1, the antenna 3 for emission of an electromagnetic wave is installed in parallel to the mounted electrode 4 for mounting the substance 2 to be processed. At the lower part of the antenna 3, the shower plate 5 is installed via the dispersion plate 9. Processing gas disperses gas in the dispersing plate 9, and is supplied into the process chamber 1 via gas holes installed at the shower plate 5. In addition, the dispersion plate 9 is divided into 2 regions, namely, the inner side and the outer side, by the O-ring 49. Processing gas supplied to the vicinity of the center of a wafer is supplied to the inside region of the dispersion plate 9 via the inner side gas piping 16-1. In addition, processing gas supplied to the vicinity of the circumference of the wafer is supplied via the gas piping 16-2 connected to the outside region of the dispersion plate 9. In this way, flow amount or composition of gas can independently be controlled at the vicinity of the center part and at the vicinity of the circumference part of the substance 2 to be processed, by which processing dimension of the inside surface of the substance 2 to be processed can uniformly be controlled.

In the process chamber 1, the exhausting unit 6 such as a turbo molecular pump is equipped with for making reduced pressure inside the process chamber 1, via the butterfly valve 3. The antenna 3 is connected with the high frequency power source for plasma generation 31, via the matching box 34-1 and the filter unit 37-1. At the outside of the process chamber 1, the coil 11 and the yoke 12 are installed, for generation of a magnetic field. Plasma is efficiently generated by electron cyclotron resonance due to interaction between the high frequency power for plasma generation emitted from the antenna 3, and the magnetic field. In addition, by controlling the magnetic field distribution, generation distribution of plasma and transportation of plasma can be controlled. The antenna 3 is connected with the high frequency power source for antenna bias 32, for applying high frequency bias power to the antenna 3, via the matching box 34-2 and the filter unit 37-1. The filter unit 37-1 is for preventing flow-in of the high frequency power for plasma generation to the high frequency power source for antenna bias 32, and for preventing flow-in of the high frequency power for antenna bias to the side of the high frequency power source for plasma generation 31. The mounted electrode 4 is connected with the high frequency power source 33 for mounted electrode bias via the matching box 34-3, to accelerate incident ions into the substance 2 to be processed.

The high frequency power for mounted electrode bias to be applied to the mounted electrode 4 and the high frequency power for antenna bias to be applied to the antenna 3 are designed to have the same frequency each other. In addition, phase difference between the high frequency power for antenna bias to be applied to the antenna 3, and the high frequency power for mounted electrode bias to be applied to the mounted electrode 4 can be controlled by the phase controller 39. Setting of the phase difference to be 180 degree improves plasma confinement, and reduces flux or energy of the incident ions to the side wall of the process chamber 1, by which generation amount of the particles caused by wall wear or the like can be reduced, or life of wall coating material or the like can be extended. In addition, the mounted electrode 4 is connected with the DC power source 38 via the filter unit 37-2, for fixing the substance 2 to be processed by electrostatic adsorption. In addition, the mounted electrode 4 is designed so that helium gas can be supplied at the back surface of the substance 2 to be processed, so as to cool the substance 2 to be processed, and the gas piping 16-3 for supplying helium gas to the inside part of the back surface of the substance 2 to be processed, and the gas piping 16-4 for supplying helium gas to the circumference part of the back surface of the substance 2 to be processed are installed, so as to independently adjust temperature at the inside part of the substance 2 to be processed, and the circumference part of the substance 2 to be processed. Flow amount of helium gas is adjusted by the mass flow controller 15.

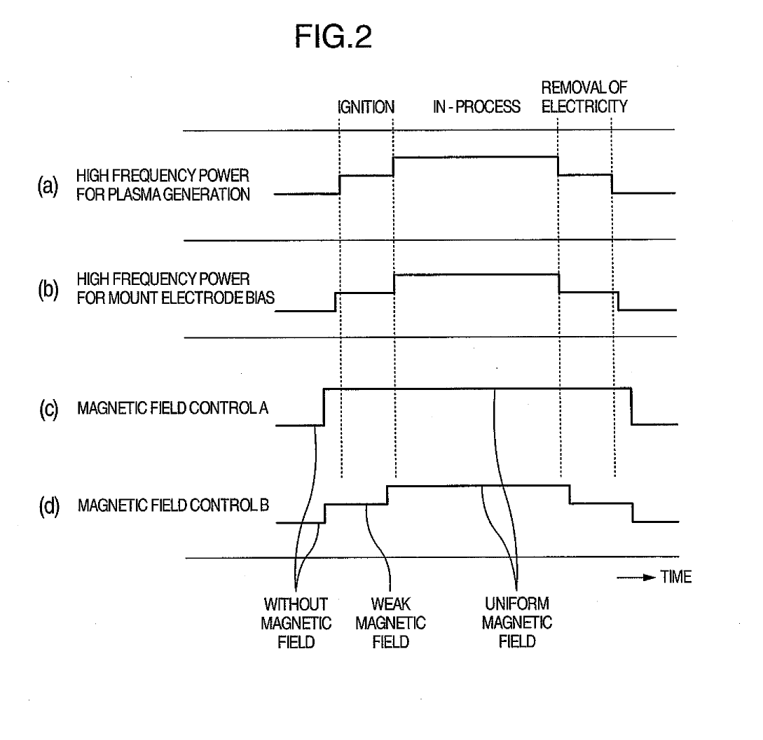

FIG. 2 shows one example of control timing of the high frequency power for plasma generation and the high frequency power for mounted electrode bias and the magnetic field intensity, in regard to discharge sequence. The magnetic field is firstly applied (magnetic field control B), followed by application of the high frequency power for mounted electrode bias and charging of the high frequency power for plasma generation. In this case, the magnetic field, the high frequency power for mounted electrode bias and the high frequency power for plasma generation to be charged are set to be weaker, compared with those in giving the predetermined processing to the substance 2 to be processed. Then, after ignition of plasma, the magnetic field, the high frequency power for plasma generation and the high frequency power for mounted electrode bias required to process the substance 2 to be processed are charged.

In addition, after completion of the predetermined processing, and in removal of electricity to cancel adsorption of the substance 2 to be processed onto the mounted electrode 4 by electrostatic adsorption, the magnetic field, the high frequency power for mounted electrode bias and the high frequency power for plasma generation are set to be weak, and after cancellation of the electrostatic adsorption, the high frequency power for plasma generation is cut off and plasma is cut off. Thereafter, the high frequency power for mounted electrode bias is cut off and finally the magnetic field is cut off.

Here, reason for charging high frequency power for mounted electrode bias before plasma ignition, and applying high frequency power for mounted electrode bias with setting weak, even during plasma ignition or after removal of electricity, is to prevent falling of the particles onto the substance 2 to be processed, during the ignition or the removal of electricity, by lowering potential of the substance 2 to be processed relative to plasma, and thus to enhance repulsion force by Coulomb force exerting between the particles and the substance 2 to be processed.

In addition, reason for applying the high frequency power for plasma generation with setting weaker than in giving the predetermined processing to the substance 2 to be processed, during plasma ignition and removal of electricity, is to make falling of the particles onto the substance 2 to be processed difficult, by making float height of the particles from the substance 2 to be processed higher by setting the sheath thick.

The magnetic field control A, in FIG. 2, shows conventional magnetic field condition where magnetic field intensity is maintained constant from before plasma ignition to removal of electricity, so as to make plasma distribution nearly uniform, namely, processing dimension of the inside of the surface of the substance 2 to be processed to become as uniform as possible. On the other hand, in the magnetic field control B, magnetic field intensity is set weaker than in giving the predetermined processing to the substance 2 to be processed, from before plasma ignition to before execution of the predetermined processing, and from during removal of electricity to after removal of electricity.

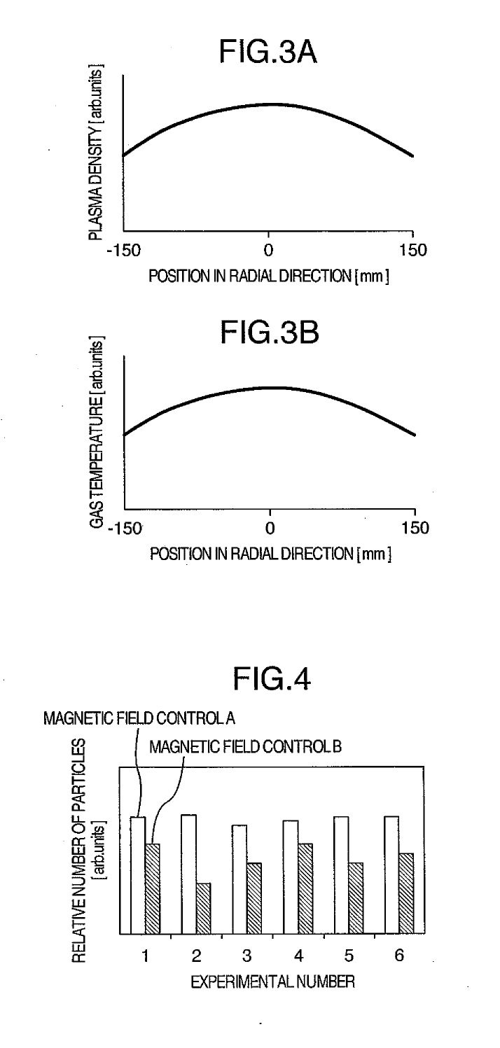

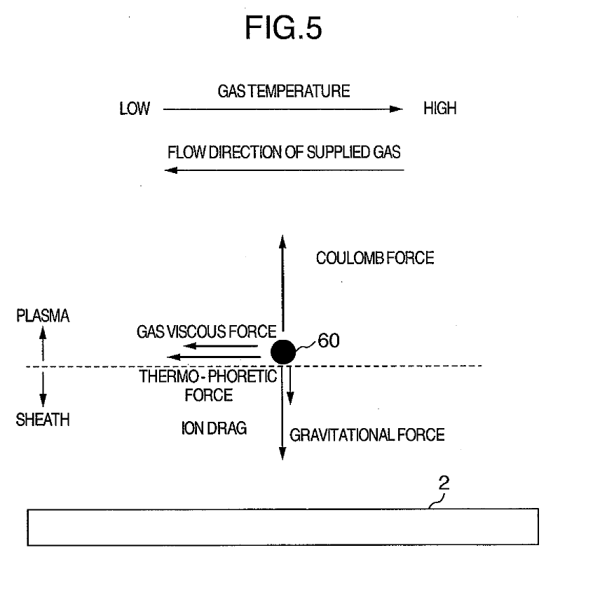

The effect of making magnetic field weak, as in the above, is explained below. In the plasma apparatus shown in FIG. 1, weakening of the magnetic field results in increase in plasma density at the vicinity of the center of the substance 2 to be processed, as shown in FIG. 3A, relative to plasma density at the vicinity of the circumference of the substance 2 to be processed, which makes the plasma distribution in a convex form at the surface of the substance to be processed, relative to the plasma distribution during the predetermined processing. When the plasma distribution is in convex form distribution, gas temperature gradient just above the substance 2 to be processed is also in a convex form, as shown in FIG. 3B. This is because plasma with an electron temperature of several tens of thousands of degree heats gas or, plasma heats the structural body inside the process chamber 1 or the substance 2 to be processed, and the structural body or the substance 2 to be processed heats gas in turn. In the case where gas temperature distribution in the radial direction just above the substance 2 to be processed is in convex distribution, namely, when gas temperature just above the center of the substance 2 to be processed is higher compared with gas temperature just above the circumference of the substance 2 to be processed, the particles floating just above the substance 2 to be processed receive thermo-phoretic force so as to be pushed toward the outside direction of the substance 2 to be processed. In addition, timing for making plasma distribution in a convex form by weakening the magnetic field is set from before plasma ignition to before the predetermined processing is executed, and from during removal of electricity to after removal of electricity, and this reason is to have priority of control the magnetic field distribution, namely the plasma distribution, so as to make the predetermined processing as uniform as possible at the surface of the substance 2 to be processed, during the predetermined processing is executed to the substance 2 to be processed.

FIG. 4 shows experimental result on comparison of the number of the particles fallen onto a wafer in carrying out etching, between under the conditions of magnetic field controls A and B in FIG. 3. The measurement was carried out using a wafer surface inspection apparatus, on the number of the particles having a particle diameter of equal to or larger than 0.15 μm. As is clear in FIG. 4, by weakening a magnetic field at the ignition and removal of electricity, the number of the particles adhered onto the substance 2 to be processed can be reduced.

Explanation was given above on a method for transporting the particles in the circumference direction of the substance 2 to be processed, by adjusting plasma distribution by the magnetic field, and thus controlling gas temperature distribution. And, in order to transport the particles floating just above the substance to be processed, in the circumference direction of a wafer, it may be attained by making gas temperature distribution in a convex form, and a method therefor includes control of plasma distribution by a factor other than the magnetic field, when control of plasma distribution is used as a method therefor.

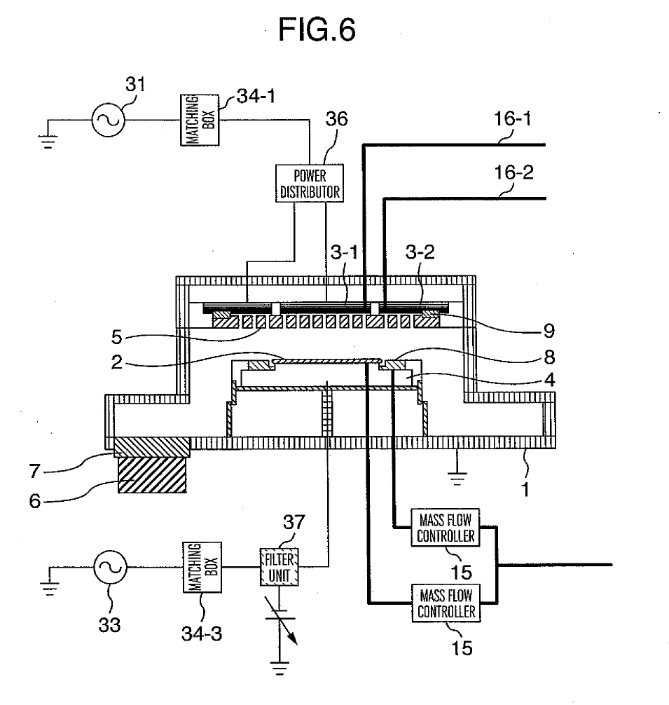

Therefore, a second embodiment of the present invention is explained below by referring to FIG. 6. Explanation of FIG. 6 on the same parts as in FIG. 1 is omitted here. In the present apparatus, the antenna 3 is electrically divided into 2 regions, namely, the inside part 3-1 and outside part 3-2. The high frequency power for plasma generation is distributed in a predetermined ratio by the power distributor 36, and one is connected to the inside part of the antenna 3, and the other is connected to the outside part of the antenna 3. In the present apparatus, by adjusting ratio of the high frequency power for plasma generation to be applied to the inside part and the outside part of the antenna 3, plasma distribution can be controlled. Therefore, by changing ratio of the high frequency power for plasma generation to be applied to the inside part of the antenna 3, and the high frequency power for plasma generation to be applied to the outside part of the antenna 3, as shown in FIG. 3A, plasma density at the vicinity of the center of a wafer can be made larger compared with that at the circumference thereof. The result is that, as shown in FIG. 3B, gas temperature distribution just above the substance 2 to be processed can be made in a convex distribution, which in turn is capable of efficiently remove the particles floating just above the substance 2 to be processed outside the substance 2 to be processed by thermo-phoretic force.

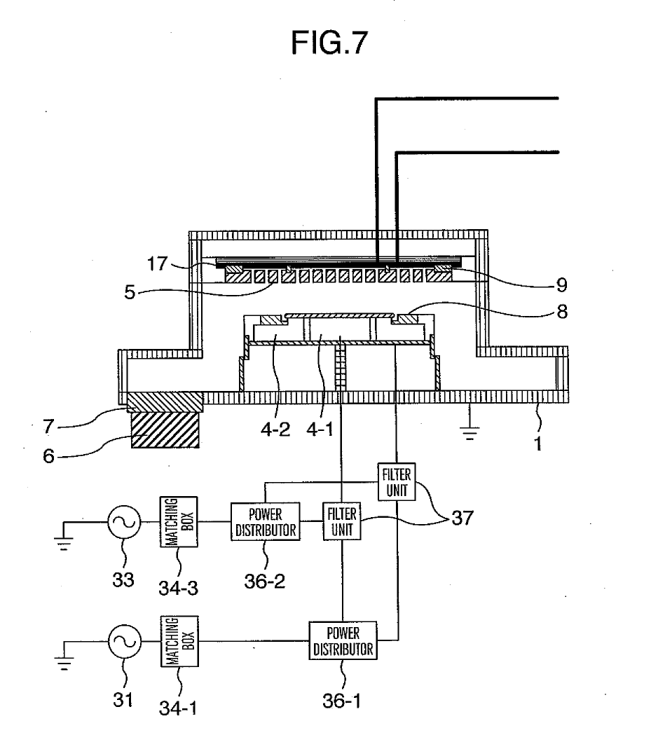

Next, a third embodiment of the present invention is explained by referring to FIG. 7. Explanation on the same parts as in FIG. 1 is omitted here. The present apparatus is a plasma processing apparatus of a type for connecting the high frequency power for plasma generation to the mounted electrode 4. The mounted electrode 4 is electrically divided into 2 regions, the inside part 4-1 and outside part 4-2 independently. The high frequency power for plasma generation is distributed in a predetermined ratio into 2 systems, by the power distributor 36-1, and one is applied to the inside part 4-1 of the mounted electrode 4, and the other to the outside part 4-2 of the mounted electrode 4. In addition, the high frequency power for mounted electrode bias to accelerate incident ions into the substance 2 to be processed is distributed in a predetermined ratio into 2 systems, by the power distributor 36-2, and one is applied to the inside part 4-1 of the mounted electrode 4, and the other to the outside part 4-2 of the mounted electrode 4. Processing gas is introduced into the process chamber 1 via the dispersion plate 9 at the lower part of the top board 17 installed opposite to the mounted electrode 4, and the shower plate 5. In such a plasma processing apparatus, by adjusting ratio of the high frequency power for plasma generation applied to the inside part 4-1 of the mounted electrode 4 and the high frequency power for plasma generation applied to the outside part 4-2 of the mounted electrode 4, plasma distribution can be controlled. In the present apparatus, by changing ratio of the high frequency power for plasma generation to be applied to the inside part of the mounted electrode 4, and the high frequency power for plasma generation to be applied to the outside part of the mounted electrode 4, in plasma ignition or removal of electricity, plasma density at the vicinity of the center of the substance 2 to be processed can be made larger relative to the vicinity of the circumference of the wafer, comparing with plasma distribution in providing the predetermined processing to the substance to be processed. Namely, plasma distribution in FIG. 3A can be formed. In this way, gas temperature distribution with a convex form, as shown in FIG. 3B, can be made, which in turn is capable of efficiently transporting the particles floating just above the substance 2 to be processed, in the circumference direction of the substance to be processed by thermo-phoretic force.

Note that, in the above embodiment, the explanation was made on the premise of carrying out removal of electricity, after completion of the predetermined processing to the substance 2 to be processed, however, this can be applied, even when the removal of electricity is not required. Namely, instead of completely cutting off the first plasma for executing the predetermined processing to the substance 2 to be processed, just after the processing, plasma may be cut off after generation of the second plasma, which is set so as to make gas temperature distribution in a convex form, compared with the first plasma, to transport the particles floating just above the substance 2 to be processed in the circumference direction of the wafer.

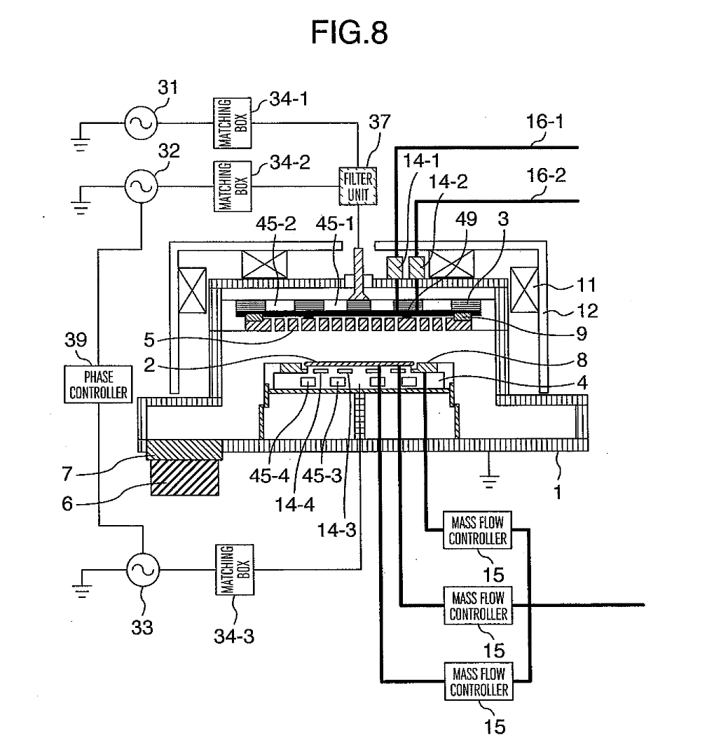

Explanation was given above on a method for controlling gas temperature distribution by controlling plasma distribution, and transporting the particles floating just above the substance to be processed in the circumference direction of the wafer by thermo-phoretic force, however, gas temperature distribution may be controlled by a method other than control of plasma distribution. Therefore, a fourth embodiment of the present invention is explained below by referring to FIG. 8. Explanation on the duplicated parts as in FIG. 1 is omitted here. In the present apparatus, the processing gas piping 16-1 for supplying the gas to the inside of the dispersion plate 9, and the processing gas piping 16-2 for supplying the gas to the outside of the dispersion plate 9 are equipped with the heater 14-1 and the heater 14-2, respectively. By these heaters, each temperature of gas supplied to the inside and gas supplied to the outside can independently be controlled. For example, by making temperature of gas supplied to the inside higher relative to that of gas supplied to the outside, gas temperature distribution in the radial direction just above the substance 2 to be processed can be made in a convex distribution. In addition, a coolant is designed to flow inside the antenna 3, and the flow passage of the coolant is separated into 2 systems, the system 45-1 for the inside part of the antenna 3, and the system 45-2 for the outside part of the antenna 3, so as to be capable of flowing the coolant with different temperature each other. By this setting, for example, by making temperature of the coolant to flow inside the antenna 3 higher compared with that of the coolant to flow outside the antenna 3, temperature distribution of the antenna 3 can be made in a convex form, resulting in a convex form of gas temperature distribution in the radial direction between the substance 2 to be processed and the antenna 3. Note that, even in the apparatus shown in FIG. 7, by installment of a coolant flow passage at the inside part of the top board 17 for independently controlling temperature of the inside part and the outside part, and by flowing a coolant with different temperature each other, it is preferable to generate temperature difference between the inside part and the outside part of the top board 17.

In addition, the mounted electrode 4 for mounting the substance 2 to be processed is equipped with the heater 14, and this heater 14 is composed of the heater 14-3 for heating the inside part of the mounted electrode 4 and the heater 14-4 for heating the circumference part thereof. Further, to adjust temperature of the mounted electrode 4, a coolant flow passage is installed at the inside of the mounted electrode 4, and by separating the coolant flow passage into the inside flow passage 45-3 and the outside flow passage 45-4, the coolant with different temperature each other is designed to flow. In this way, for example, by changing flow amount or temperature of the coolant flowing the inside flow passage and the outside flow passage, so as to make temperature at the vicinity of the center of the mounted electrode 4 higher than that at the vicinity of the circumference of the mounted electrode 4, in the time other than providing the predetermined processing to the substance 2 to be processed, compared with the time providing the predetermined processing, gas temperature distribution in the radial direction just above the substance 2 to be processed can be made higher and in a convex distribution at the vicinity of the center. In addition, to cool the substance 2 to be processed, helium gas is set to be supplied between the mounted electrode 4 and the substance 2 to be processed, and also to cool the focusing ring 8 as well as the substance 2 to be processed, helium gas is set to be supplied also to the back surface of the focusing ring 8. By cooling the focusing ring 8, temperature gradient of gas temperature in the radial direction just above the substance 2 to be processed can be made higher.

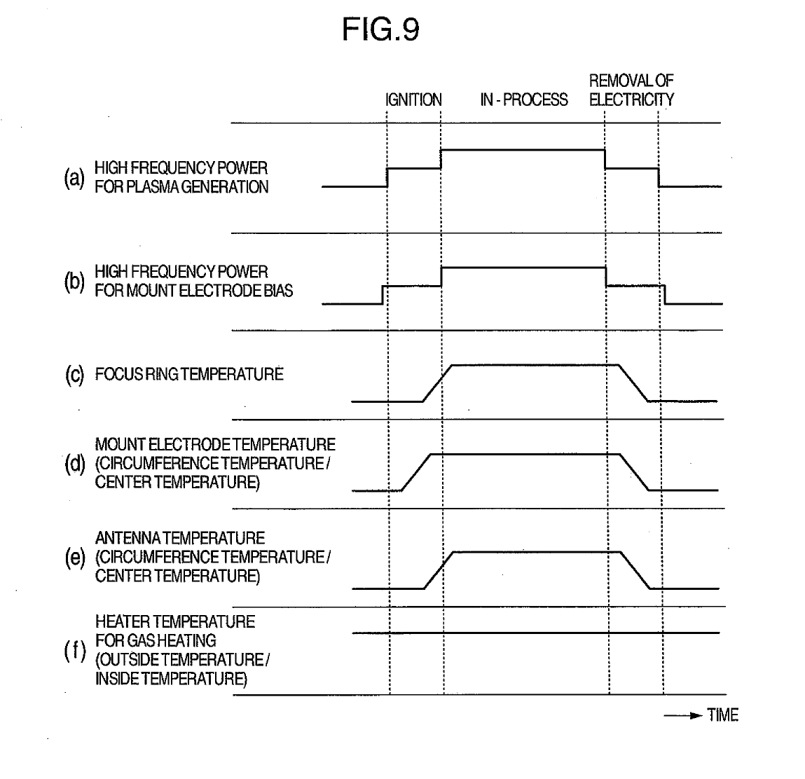

FIG. 9 shows control timing. Temperature of the mounted electrode 4 and temperature of the antenna 3 are set, so that outside temperature is lower relative to the center temperature, in plasma ignition and removal of electricity. On the other hand, during plasma processing, temperature of the mounted electrode 4 and temperature of the antenna 3 are changed, so as to attain uniform processing at the whole surface of the substance 2 to be processed. Also regarding to the focusing ring 8, cooling capability is enhanced, so that temperature in ignition and removal of electricity is made lower compared with that during the processing. Temperature of the focusing ring 8 during the processing is adjusted so as to attain uniform processing at the surface of the substance 2 to be processed. The heaters 14-3 and 14-4 for heating gas were set, so that temperature of gas supplied from the inside is always higher than that of gas supplied to the outside. However, in the case where adjustment pf gas temperature distribution is necessary to enhance uniformity at the surface of the substance 2 to be processed during the predetermined processing, temperature of the heater 14 may be changed during the processing and ignition, and during processing and removal of electricity. Thus, a control system of gas temperature distribution by a method other than control of plasma distribution is effective during plasma discharge, as well as, in particular, in no plasma ignition, such as before or after plasma discharge.

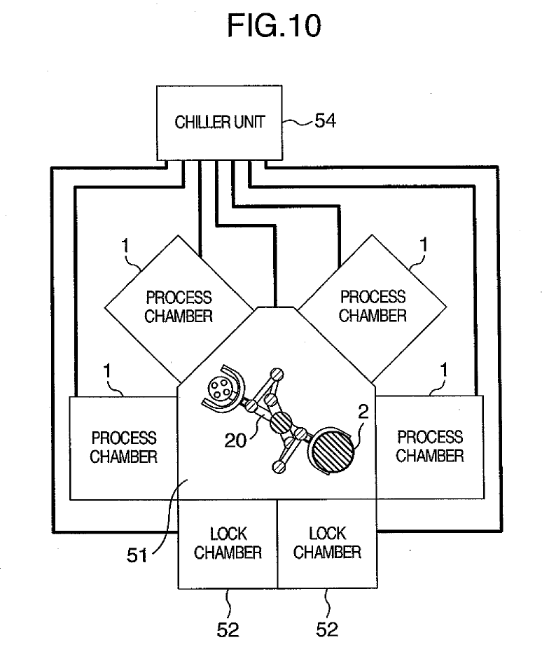

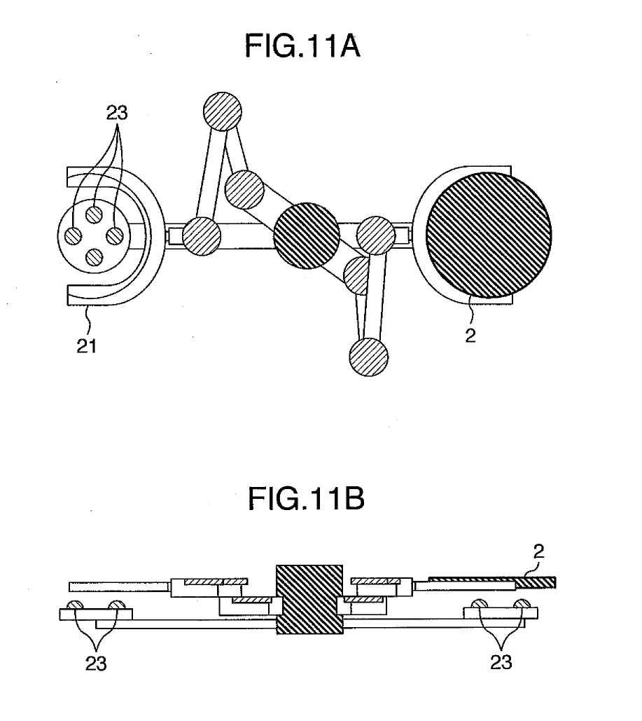

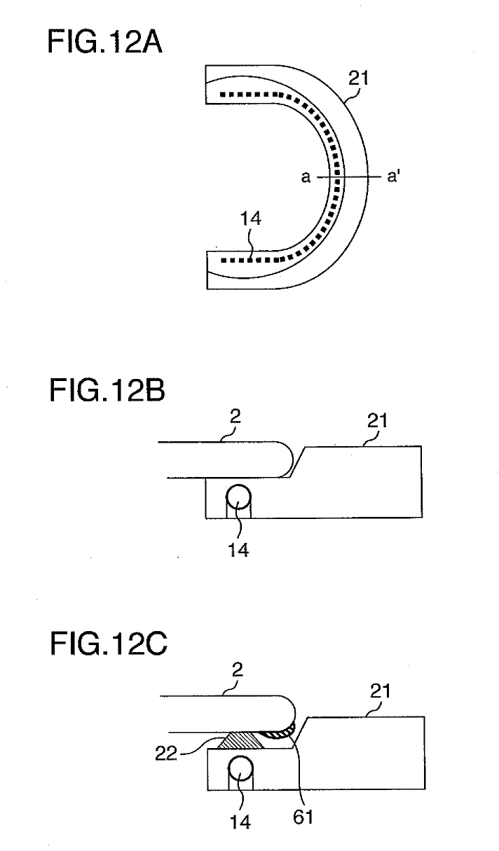

Explanation was given above on the particles transportation control using thermo-phoretic force inside the plasma process chamber 1, however, the particles transportation control using thermo-phoretic force is also effective in the conveyance chamber 51 or the lock chamber 52. Therefore, a fifth embodiment of the present invention is explained below by referring to FIGS. 10 to 14. FIG. 10 is an overhead view showing outline of the whole plasma processing apparatus. The present plasma processing system is equipped with 4 plasma process chambers 1, the conveyance chamber 51 and 2 lock chambers 52. First of all, reducing function of the particles using thermo-phoretic force inside the conveyance chamber 51 is explained. FIGS. 11A and 11B show outline of the conveyance robot 20 installed inside the conveyance chamber 51. FIG. 11A is an overhead view and FIG. 11B is a side view, both showing the outline. In addition, FIGS. 12A to 12C show the vicinity of the conveyance arm 21 for mounting the substance 2 to be processed in the conveyance robot 20. FIG. 12A is an overhead view showing the outline, and FIGS. 12B and 12C show 2 kinds of cross-section examples along the a-a′ line in FIG. 11A. The conveyance arm 21 is equipped with the heater 14 for heating the substance 2 to be processed mounted on the conveyance arm 21. The heater 14 is arranged, for example, along a part where a wafer is mounted, as shown by a broken line in FIG. 12 A. In addition, the heater 14 is designed to have built-in structure in the conveyance arm 21, as shown in FIG. 12B or FIG. 12C. The surface for mounting the substance 2 to be processed is designed to be flat, as sown in FIG. 12B, or designed so that the circumference part of the back surface of the substance 2 to be processed does not contact with the conveyance arm 21, by the pedestal 22, as shown by FIG. 12C. In FIG. 12B, wide installment areas of the substance 2 to be processed and the conveyance arm 21 provide higher heating capability of the substance 2 to be processed by the heater 14, compared with that in FIG. 12C; however, in FIG. 12C, the sediment 61 adhered onto the circumference of the back surface of the substance 2 to be processed does no t contact with the conveyance arm 21, therefore, the sediment peels off by contact with the conveyance arm 21, and thus generation of the particles can be prevented. In addition, as shown in FIG. 11, to accelerate heating of the substance 2 to be processed mounted on the conveyance arm 21, the lamp 23 was installed at the lower part of the conveyance arm 21. The substance 2 to be processed is heated by light emitted from this lamp 23. The combination with heating by the heater 14 enhances heating capability of the substance 2 to be processed. In this way, the substance 2 to be processed is heated, so that temperature of the substance 2 to be processed is made higher compared with that of the inside wall or structural body of the process chamber 1, and the conveying robot 20, which contributed to no-adherence of the particles onto the substance 2 to be processed by thermo-phoretic force.

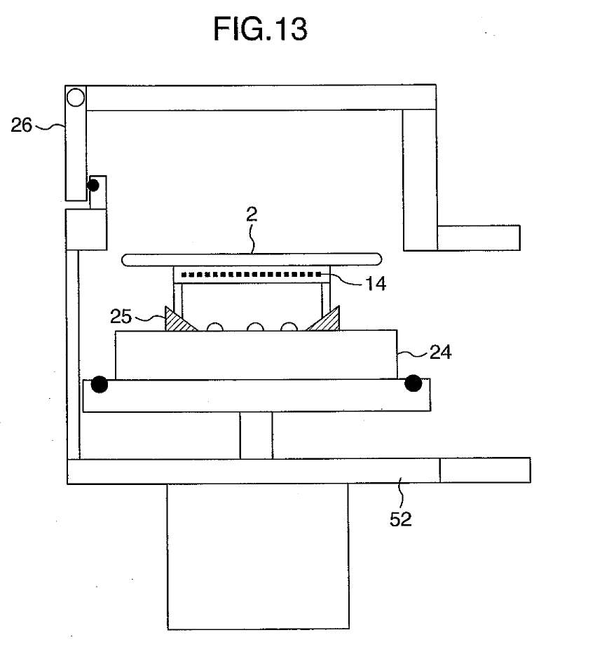

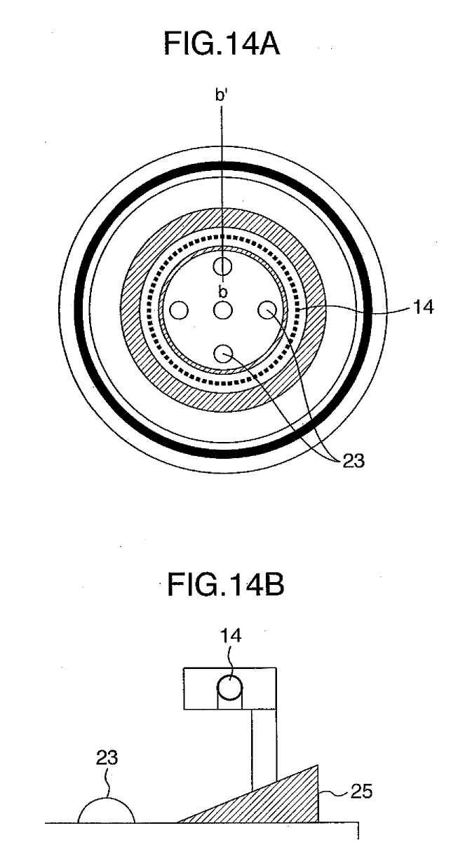

FIG. 13 shows outline of the cross-section of the lock chamber 52. FIG. 14A is an overhead view showing outline of the wafer stage 24 installed inside the lock chamber 52, and FIG. 14B shows outline between b-b′ of FIG. 14A. The stage 24 for the substance to be processed is installed with the heater 14 and the lamp 23 for heating the substance 2 to be processed. The heater 14 heats a part for mounting the substance 2 to be processed, and in this way, the substance 2 to be processed is heated. Further, the lamp 23 enhances heating capability. In addition, because heating of a structural body other than the substance 2 to be processed, or the inner wall of the lock chamber 52 could suppress sufficient raising of temperature of the substance 2 to be processed relative to the structural body or the inside wall, heating of other than the substance 2 to be processed is suppressed by the reflection plate 25. In addition, because thermo-phoretic force utilizes a force generated by gas temperature gradient, gas with a pressure of equal to or higher than a certain level is required. Therefore, for example, to adjust the gas pressure to equal to or higher than 1 Pa, the conveyance chamber 51 or the lock chamber 52 is equipped with a gas supplying unit and a gas exhausting unit. In addition, because larger gas temperature gradient is effective for the particles not to adhere onto the substance 2 to be processed by thermo-phoretic force, the inner wall or the structural body of the process chamber 1 or the conveyance chamber 51 or the lock chamber 52 is designed to be cooled by connection of the chiller unit 54 to the process chamber 1 or the conveyance chamber 51 or the lock chamber 52. In this way, temperature of the substance 2 to be processed is made higher than that of the inner wall or the structural body of the process chamber 1, or the conveyance chamber 51 or the lock chamber 52.

As described above, in the present invention, the particles adhering onto the substance to be processed was reduced by forming gas temperature gradient in a positive way, and thus removing, by thermo-phoretic force, the particles from the substance to be processed. This reduction is capable of enhancing yield of the semiconductor device.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor device manufacturing apparatus comprising:
a process chamber;
a conveyance chamber;
a conveyance robot;
a lock chamber; and
a heating unit for reducing adherence of particles onto a substance to be processed by a thermo-phoretic force;
wherein said heating unit enables control of a temperature of the substance to be processed to be higher than a temperature of an inner wall or structural body of the process chamber or the conveyance chamber or the conveyance robot or the lock chamber, in conveying the substance to be processed.

2. The semiconductor device manufacturing apparatus according to claim 1, wherein the heating unit includes a heater or a lamp for heating the substance to be processed, set up on the conveyance robot which is installed in the conveyance chamber.

3. The semiconductor device manufacturing apparatus according to claim 1, wherein the heating unit includes a heater or a lamp for heating the substance to be processed, at a stage for mounting the substance to be processed which is installed in the lock chamber.

4. A semiconductor device manufacturing apparatus comprising:
a process chamber;
a conveyance chamber;
a lock chamber; and
a temperature adjusting unit for reducing adherence of particles onto a substance to be processed by a thermo-phoretic force;
wherein the temperature adjusting unit enables adjustment of a temperature of an inner wall or structural body of the process chamber or the conveyance chamber or the lock chamber to be lower than a temperature of the substance to be processed, in conveying the substance to be processed.
